(19) United States
(12) Patent Application Publication
(10) Pub. No.: US 2022/0230986 A1
(43) Pub. Date: Jul. 21, 2022

(54) Semiconductor Assembly Packaging Method, Semiconductor Assembly and Electronic Device

(71) Applicant: Yibu Semiconductor Co., Ltd., Shanghai (CN)

(72) Inventor: Weiping LI, Shanghai (CN)

(21) Appl. No.: 17/578,396

(22) Filed: Jan. 18, 2022

Related U.S. Application Data
(63) Continuation-in-part of application No. 17/568,293, filed on Jan. 4, 2022.

(30) Foreign Application Priority Data
Jan. 18, 2021 (CN) 202110062475.3

(51) Int. Cl. H01L 23/00; H01L 23/544; H01L 21/48; H01L 25/00

(52) U.S. Cl. CPC H01L 24/81; H01L 23/544; H01L 21/4853; H01L 24/14; H01L 2224/1403; H01L 2223/54426; H01L 2224/8114; H01L 2224/81203; H01L 25/50

(57) ABSTRACT

A semiconductor assembly packaging method comprises aligning and attaching at least one first semiconductor device to a first side of an interconnect board by forming a plurality of first alignment solder joints; aligning and attaching at least one second semiconductor device to a second side of the interconnect board by forming a plurality of second alignment solder joints; pressing the at least one first semiconductor device toward the interconnect board while the first alignment solder joints are in a molten or partially molten state to form first interconnect bonds between the at least one first semiconductor device and the interconnect board; and pressing the at least one second semiconductor device toward the interconnect board while the second alignment solder joints are in a molten or partially molten state to form second interconnect bonds between the at least one second semiconductor device and the interconnect board. A semiconductor component is made using the method.

### CROSS REFERENCE TO RELATED APPLICATIONS

This application claims the benefit of priority under the Paris Convention to Chinese Patent Application No. CN202110062475.3, filed Jan. 18, 2021, entitled “Semiconductor Assembly Packaging Method, Semiconductor Assembly and Electronic Device,” and is a continuation-in-part application of U.S. patent application Ser. No. 17/568,293 entitled “Semiconductor Assembly Packaging Method, Semiconductor Assembly and Electronic Device,” filed Jan. 4, 2022, which claims the benefit of priority under the Paris Convention to Chinese Patent Application No. CN202110002410.X, filed Jan. 4, 2021, entitled “Semiconductor Assembly Packaging Method, Semiconductor Assembly and Electronic Device,” each of which is incorporated by reference herein in its entirety. This application is related to co-pending U.S. patent application Ser. No. 17/535,983, entitled “Semiconductor Packaging Method, Semiconductor Assembly and Electronic Device Comprising Semiconductor Assembly,” filed Nov. 26, 2021, U.S. patent application Ser. No. 17/535,986, entitled “Semiconductor Packaging Method, Semiconductor Assembly and Electronic Device Comprising Semiconductor Assembly,” filed Nov. 26, 2021, U.S. patent application Ser. No. 17/562,936, entitled “Semiconductor Packaging Method, Semiconductor Assembly and Electronic Device Comprising Semiconductor Assembly,” filed Dec. 27, 2021, and U.S. patent application Ser. No. 17/562,939, entitled “Semiconductor Packaging Method, Semiconductor Assembly and Electronic Device Comprising Semiconductor Assembly,” filed Dec. 27, 2021, each of which is incorporated by reference herein in its entirety.

### FIELD OF THE INVENTION

The present application relates to the technical field of semiconductor manufacturing, in particular to a semiconductor assembly packaging method, a semiconductor assembly and electronic device.

### BACKGROUND

In the manufacture of microelectronic products, a semiconductor device (e.g., one or more packaged chips or dies) is usually soldered on an interconnect board (e.g., a substrate or an interposer) to obtain a semiconductor assembly, and the semiconductor assembly is then interconnected with other components to form an electronic product or system.

How to realize high-precision placement and fixation of one or more semiconductor devices on an interconnect board with lower equipment and process cost is a technical problem to be urgently solved.

### SUMMARY

To solve the above technical problems, the present application is directed to providing a semiconductor device assembly packaging method, a semiconductor device, and an electronic apparatus, which address the shortcomings of the existing technologies. In some embodiments, a method of packaging a semiconductor assembly comprises providing an interconnect board, at least one first semiconductor device and at least one second semiconductor device. In some embodiments, a plurality of first connection terminals and a plurality of first alignment solder parts are formed on a first surface on a first side of the interconnect board, and a plurality of second connection terminals and a plurality of second alignment solder parts are formed on a second surface on a second side of the interconnect board, the second side opposing the first side. A plurality of third connection terminals and a plurality of third alignment solder parts are formed on active surface(s) of the at least one first semiconductor device, and a plurality of fourth connection terminals and a plurality of fourth alignment solder parts are formed on active surface(s) of the at least one second semiconductor device. In some embodiments, the first connection terminals and the third connection terminals are in one-to-one correspondence, the first alignment solder parts and the third alignment solder parts are in one-to-one correspondence, and the height sum of any first connecting terminal and its corresponding third connecting terminal is smaller than the height sum of any first alignment solder part and its corresponding third alignment solder part. Likewise, the second connection terminals and the fourth connection terminals are in one-to-one correspondence, the second alignment solder parts and the fourth alignment solder parts are in one-to-one correspondence, and the height sum of any second connecting terminal and its corresponding fourth connecting terminal is smaller than the height sum of any second alignment solder part and its corresponding fourth alignment solder part.

In some embodiments, the method further comprises placing the at least one first semiconductor device on the first side of the interconnect board such that each third alignment solder part is substantially or approximately aligned with a corresponding first alignment solder part; and respectively bonding the first alignment solder parts and the corresponding third alignment solder parts into respective first alignment solder joints in a molten or partially molten state using a soldering process to more accurately align the at least one semiconductor device to target position(s) on the interconnect board. In some embodiments, a space is reserved between the first connection terminals and the corresponding third connection terminals.

In some embodiments, the method further comprises placing the at least one second semiconductor device on the first side of the interconnect board such that each fourth alignment solder part is substantially or approximately aligned with a corresponding second alignment solder part; and respectively bonding the fourth alignment solder parts and the corresponding second alignment solder parts into respective second alignment solder joints in a molten or partially molten state using a soldering process to more accurately align the at least one second semiconductor device to target position(s) on the interconnect board. In some embodiments, a space is reserved between the fourth connection terminals and the corresponding second connection terminals.

In some embodiments, the method further comprises pressing the at least one first semiconductor device toward the interconnect board while maintaining the alignment between the at least one first semiconductor device and while the first alignment solder joints are in a molten or partially molten state, so that each third connection terminal and its corresponding first connection terminal are joined and bonded to each other to form a corresponding first interconnection bond.

In some embodiments, the method further comprises pressing the at least one second semiconductor device toward the interconnect board while maintaining the alignment between the at least one second semiconductor device and while the second alignment solder joints are in a molten or partially molten state, so that each fourth connection terminal and its corresponding second connection terminal are joined and bonded to each other to form a corresponding second interconnection bond.

In some embodiments, after respectively bonding the first alignment solder parts and the corresponding third alignment solder parts into respective first alignment solder joints in a molten or partially molten state, the method further comprises solidifying or substantially solidifying the first alignment solder joints; and after the first alignment solder joints are in a solidified or substantially solidified state, flipping the interconnect board with its second side facing upward before placing the at least one second semiconductor device on the second sider of the interconnect board.

In some embodiments, the first connection terminals and/or the third connection terminals are in a molten or partially molten state when the at least one first semiconductor device is pressed toward the interconnect board.

In some embodiments, the second connection terminals and/or the fourth connection terminals are in a molten or partially molten state when the at least one second semiconductor device is pressed toward the interconnect board.

In some embodiments, each third connection terminal and its corresponding first connection terminal are bonded to each other by thermocompression to form a corresponding first interconnection bond when the at least one first semiconductor device is pressed toward the interconnect board.

In some embodiments, each fourth connection terminal and its corresponding second connection terminal are bonded to each other by thermocompression to form a corresponding second interconnection bond when the at least one second semiconductor device is pressed toward the interconnect board.

In some embodiments, the method further comprises releasing the pressure on the at least one first semiconductor device after the first alignment solder joints and/or the first interconnection bonds are solidified or substantially solidified; and releasing the pressure on the at least one second semiconductor device after the second alignment solder joints and/or the second interconnection bonds are solidified or substantially solidified.

In some embodiments, a method of packaging a semiconductor assembly comprises providing an interconnect board, a first semiconductor device, and at least one second semiconductor device. A plurality of first connection terminals and a plurality of first alignment solder parts are formed on a first surface on a first side of the interconnect board, and a plurality of second connection terminals and a plurality of second alignment solder parts are formed on a second surface on a second side of the interconnect board, the second side opposing the first side. A plurality of third connection terminals and a plurality of third alignment solder parts are formed on active surface(s) of the at least one first semiconductor device, and a plurality of fourth connection terminals and a plurality of fourth alignment solder parts are formed on active surface(s) of the at least one second semiconductor device. The first connection terminals and the third connection terminals are in one-to-one correspondence, the first alignment solder parts and the third alignment solder parts are in one-to-one correspondence, and the height sum of any first connecting terminal and its corresponding third connecting terminal is smaller than the height sum of any first alignment solder part and its corresponding third alignment solder part. Likewise, the second connection terminals and the fourth connection terminals are in one-to-one correspondence, the second alignment solder parts and the fourth alignment solder parts are in one-to-one correspondence, and the height sum of any second connecting terminal and its corresponding fourth connecting terminal is smaller than the height sum of any second alignment solder part and its corresponding fourth alignment solder part.

In some embodiments, the method further comprises placing the at least one first semiconductor device on the first side of the interconnect board such that each third alignment solder part is substantially or approximately aligned with a corresponding first alignment solder part; and respectively bonding the first alignment solder parts and the corresponding third alignment solder parts into respective first alignment solder joints in a molten or partially molten state using a soldering process to more accurately align the at least one semiconductor device to target position(s) on the interconnect board. In some embodiments, a space is reserved between the first connection terminals and the corresponding third connection terminals.

In some embodiments, the method further comprises pressing the at least one first semiconductor device toward the interconnect board while maintaining the alignment between the at least one first semiconductor device and while the first alignment solder joints are in a molten or partially molten state, so that each third connection terminal and its corresponding first connection terminal are joined and bonded to each other to form a corresponding first interconnection bond; and releasing the pressure on the at least one first semiconductor device after the first alignment solder joints and/or the first interconnection bonds are solidified or substantially solidified.

In some embodiments, the method further comprises, after the first alignment solder joints are in a solidified or substantially solidified state, flipping the interconnect board with its second side facing upward before placing the at least one second semiconductor device on the second sider of the interconnect board; placing the at least one second semiconductor device on the first side of the interconnect board such that each fourth alignment solder part is substantially or approximately aligned with a corresponding second alignment solder part; and respectively bonding the fourth alignment solder parts and the corresponding second alignment solder parts into respective second alignment solder joints in a molten or partially molten state using a soldering process to more accurately align the at least one second semiconductor device to target position(s) on the interconnect board. In some embodiments, a space is reserved between the fourth connection terminals and the corresponding second connection terminals.

In some embodiments, the method further comprises pressing the at least one second semiconductor device toward the interconnect board while maintaining the alignment between the at least one second semiconductor device and while the second alignment solder joints are in a molten or partially molten state, so that each fourth connection terminal and its corresponding second connection terminal are joined and bonded to each other to form a corresponding second interconnection bond; and releasing the pressure on the at least one second semiconductor device after the second alignment solder joints and/or the second interconnection bonds are solidified or substantially solidified.

In some embodiments, the method further comprises maintaining alignment and uniform spacing between the at least one first semiconductor device and the interconnect board while the interconnect board is flipped to allow assembling of the at least one second semiconductor device to the interconnect board.

In some embodiments, the method further comprises.

In some embodiments, the method further comprises.

In some embodiments, after respectively bonding the first alignment solder parts and the corresponding third alignment solder parts into respective first alignment solder joints in a molten or partially molten state, the method further comprises solidifying or substantially solidifying the first alignment solder joints; and after the first alignment solder joints are in a solidified or substantially solidified state, flipping the interconnect board with its second side facing upward before placing the at least one second semiconductor device on the second sider of the interconnect board.

In some embodiments, the first connection terminal and/or the third connection terminal are in a molten or partially molten state when the at least one first semiconductor device is pressed toward the interconnect board.

In some embodiments, the second connection terminals and/or the fourth connection terminals are in a molten or partially molten state when the at least one second semiconductor device is pressed toward the interconnect board.

Compared with existing technologies, the embodiments described herein take advantage of the minimum surface energy principle and allow molten and partially molten solder joints automatically introducing each semiconductor device to its target location to achieve surface energy minimization. Thus, the first alignment solder joints allow each of the at least one semiconductor device and the at least one second semiconductor device to be securely and accurately fixed at its target location after solidification and substantial solidification thereof. By optimizing the design for the first and third alignment solder parts, and the second and fourth alignment solder parts (e.g., for aspects of volume, geometry, composition, location, distribution, and quantity, etc.), the most accurate, efficient, and reliable self-alignment capability can be achieved. The accurate alignment of the at least one first semiconductor device and the at least one second semiconductor device also ensures the accurate alignment of the first connection terminals and the third connection terminals, and the second connection terminals and the fourth connection terminals. A certain degree of placement deviation is allowed when picking up and placing the at least one first semiconductor device and the at least one second semiconductor device in view of the self-alignment capability of the alignment solder joints, so that the requirement on the placement accuracy of the at least one first semiconductor device and the at least one second semiconductor device can be significantly reduced, and the speed of the semiconductor device picking-up and placing operations can be significantly increased, thereby improving the efficiency, and reducing process and equipment costs.

### BRIEF DESCRIPTION OF THE DRAWINGS

FIGS. 1a-1d are schematic flow charts of several semiconductor assembly packaging methods according to some embodiments.

FIGS. 2-8 are cross-sectional views schematically illustrating various stages of a semiconductor assembly packaging method according to some embodiments.

The reference numerals in the drawings include:
1. interconnect board;
111. first alignment solder part;
112. first connection terminal;
121. second alignment solder part;
122. second connection terminal;
2. first semiconductor device;
21. third alignment solder part;
22. third connection terminal;
3. second semiconductor device;
31. fourth alignment solder part;
32. fourth connection terminal;
a1. first alignment solder joint;
a2. second alignment solder joint;
b1. first interconnect bond;
b2. second interconnect bond;
13. external pad; and
131. solder bump.

### DETAILED DESCRIPTION OF THE EMBODIMENTS

In the present application, the terms such as “including” or “having,” or the like, are intended to indicate the presence of the disclosed features, integers, steps, acts, components, parts, or combinations thereof, but do not preclude the presence or addition of one or more other features, integers, steps, acts, components, parts, or combinations thereof.

Certain embodiments or certain features of various embodiments may be combined with each other without conflict. Examples of embodiments will be described in detail below with reference to the attached drawings.

Semiconductor devices are core components of modern electronic devices or products. As used herein, the term “semiconductor device” may refer to a chip (also interchangeably referred to as die, integrated circuit) produced by a chip factory (fab), i.e., a chip that has not been packaged after wafer dicing and testing, and which may typically have only interconnect pads for external connection. The semiconductor device may also be a pre-processed (at least partially packaged) chip, such as with interconnect bumps (bump) formed on the interconnect pads, or may have additional structures, such as stacked chips and packaged chips, as desired. Semiconductor devices may also include discrete semiconductor devices and multi-chip semiconductor devices. Discrete semiconductor devices include, for example, single digital logic processors, transistors, bipolar transistors, field effect transistors, active devices such as integrated circuits, and passive devices such as diodes, chip resistors, capacitors, inductors, and Integrated Passive Devices (IPDs). Multi-chip semiconductor devices, such as a module of a image sensor (CIS) and an image processor (ASIC), a Central Processing Unit (CPU), and a dynamic memory (DRAM). A semiconductor device according to the present application may be in a packaged state or may be in a bare chip state.

Some embodiments include technical solutions on how to solder a semiconductor device to an interconnect board to achieve interconnection of signals between the semiconductor device and the interconnect board.

The term “active surface” as used herein generally refers to a surface on a front (or active) side of a semiconductor device having a circuit function, including connection terminals, e.g., interconnect pads (or interconnect bumps formed on the interconnect pads) thereon, and may also be interchangeably referred to as a front surface or a functional surface. A surface having no circuit function on an opposing back side of the semiconductor device may be interchangeably referred to as a passive surface or a back surface.

The term “connection terminal” as used herein generally refers to an interconnect pad or an interconnect bump on the active surface of a semiconductor device, or an interconnection bond or interconnection bump on an interconnect board.

The term “alignment solder part” as used herein generally refers to a structure that may be aligned and soldered to a corresponding other alignment solder part for alignment by soldering methods known in the art. Examples in some embodiments are described further below with reference to the drawings.

In some embodiments, an interconnect board may include leads (e.g., conductive traces, wires, and/or through-vias that are not shown in the drawings) between “connection terminals” on the interconnect board, thereby realizing interconnection between different “connection terminals” on a semiconductor device assembled on the interconnect board, as described in co-pending U.S. patent application Ser. No. 17/562,936, filed Dec. 27, 2021, entitled “Method for Forming Semiconductor Package and Semiconductor Package,” which is incorporated herein by reference in its entirety.

Herein, substantial alignment or approximate alignment between two alignment solder parts means that the two alignment solder parts contact each other but may offset from each other by as much as exceeding an upper limit value allowed by an applicable design specification for the misalignment between an interconnect board and a semiconductor device in a finished product.

Herein, “precisely alignment” between the interconnect board and the semiconductor device means that the deviation between a finished position and a target position for the semiconductor device on the interconnect board is less than a maximum deviation between the two positions allowed in an applicable design specification. If an alignment solder joint is formed between the interconnect board and the semiconductor device, the position deviation of the alignment solder joint is within an allowable maximum deviation of the applicable design specification. If interconnect solder bonds are formed between the semiconductor device on the interconnect board, the position deviation of the interconnect solder bonds is within an allowable maximum deviation of the applicable design specification.

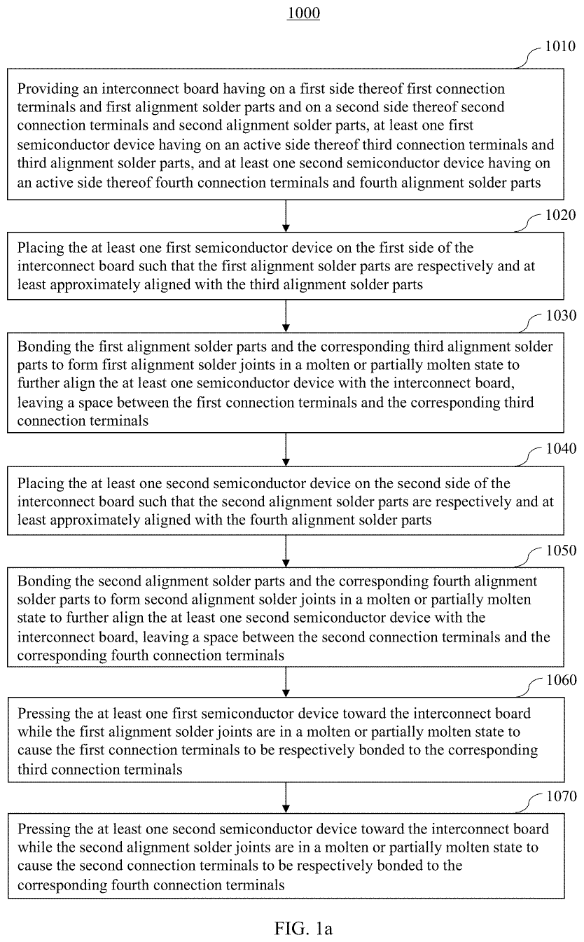

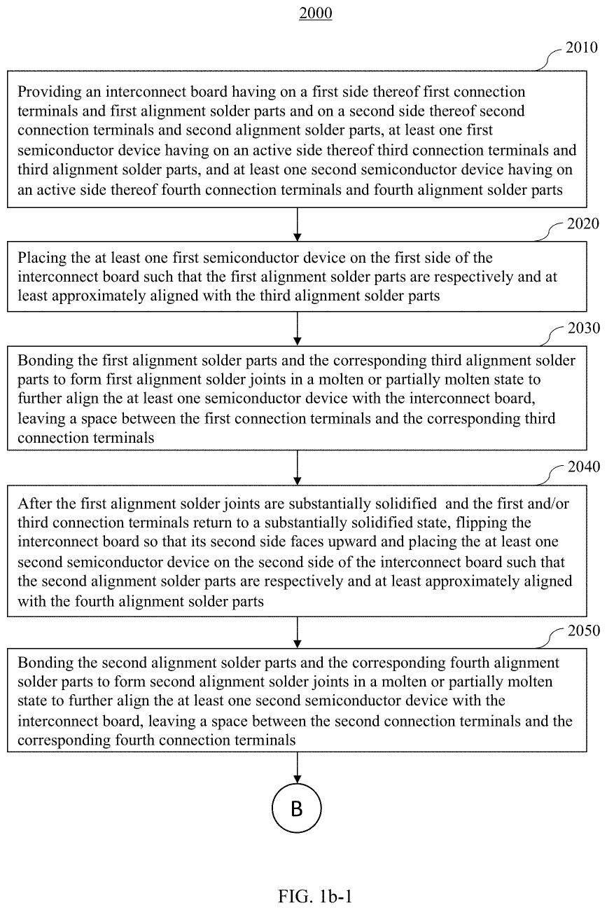

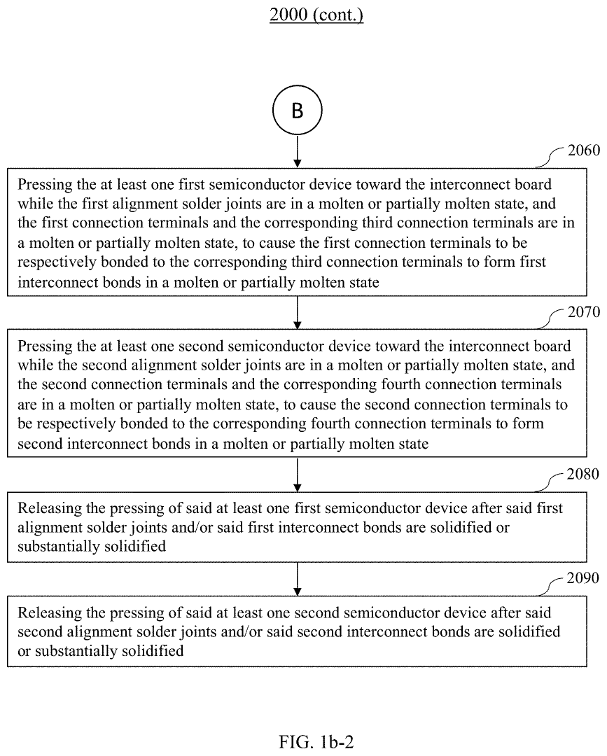

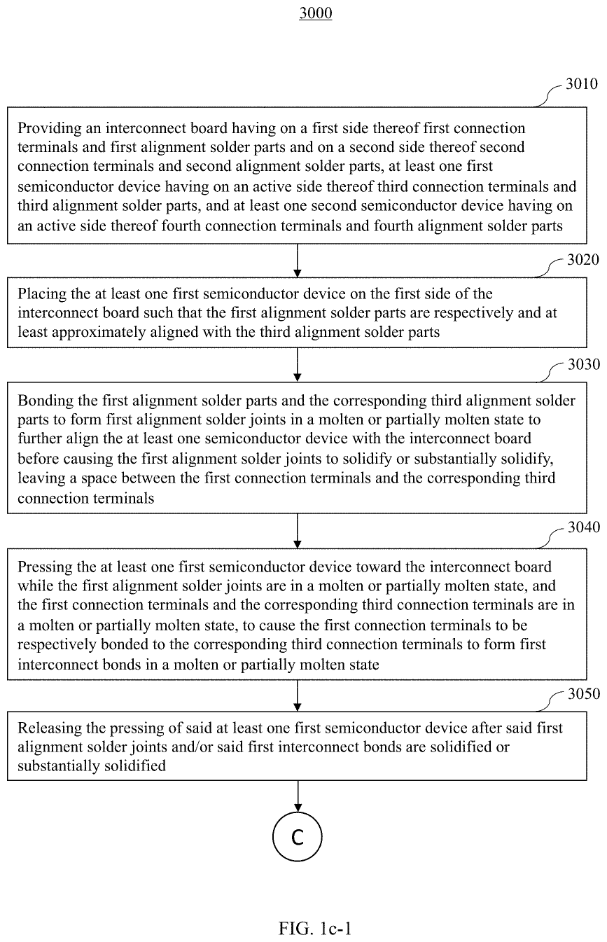

As shown in FIG. 1a, a semiconductor assembly packaging method 1000 according to some embodiments includes steps 1010-1070, as described below.

Step 1010—providing an interconnect board, at least one first semiconductor device, and at least one second semiconductor device.

In some embodiments, a plurality of first connection terminals and a plurality of first alignment solder parts are formed on a first surface on a first side of the interconnect board, and a plurality of second connection terminals and a plurality of second alignment solder parts are formed on a second surface on a second side of the interconnect board, the second surface being opposite to the first surface. In some embodiments, a plurality of third connection terminals and a plurality of third alignment solder parts are formed on an active surface of each of the at least one first semiconductor device, and a plurality of fourth connection terminals and a plurality of fourth alignment solder parts are formed on an active surface of each of the at least one second semiconductor device. In some embodiments, the first connection terminals and the third connection terminals are in one-to-one correspondence, the first alignment solder parts and the third alignment solder parts are in one-to-one correspondence. Likewise, the second connection terminals and the fourth connection terminals are in one-to-one correspondence, the second alignment solder parts and the fourth alignment solder parts are in one-to-one correspondence. In some embodiments, a sum of a height of any first connection terminal and that of a corresponding third connection terminal is smaller than a sum of a height of any one of the first alignment solder parts and that of a corresponding one of the third alignment solder parts. Likewise, a sum of a height of any second connection terminal and that of a corresponding fourth connection terminal is smaller than a sum of a height of any one of the second alignment solder parts and that of a corresponding one of the fourth alignment solder parts.

Step 1020—placing the at least one first semiconductor device on the first side of the interconnect board such that the first alignment bond is substantially aligned with the corresponding third alignment bond.

Step 1030—bonding the first alignment solder part parts and the corresponding third alignment solder parts to form first alignment solder joints in a molten or partially molten state using a soldering process to more accurately align the at least one first semiconductor device. In some embodiments, the first connection terminals and the corresponding third connection terminals are spaced apart from each other after the first alignment solder joints are formed.

Step 1040—placing the at least one second semiconductor device on the second side of the interconnect board such that the second alignment bond is substantially aligned with a corresponding fourth alignment bond.

Step 1050—bonding the second alignment solder part parts and the corresponding fourth alignment solder part parts to form second alignment solder joints in a molten or partially molten state using a soldering process to more accurately align the at least one second semiconductor device. In some embodiments, the second connection terminals and the corresponding fourth connection terminals are spaced apart from each other after the second alignment solder joints are formed.

Step 1060—pressing the at least one first semiconductor device towards the interconnect board while the first alignment solder joints are in a molten or partially molten state to bond the first connection terminals and the corresponding third connection terminals into stable interconnection bonds, while maintaining alignment of the first semiconductor device.

Step 1070—pressing the at least one second semiconductor device towards the interconnect board while the second alignment solder parts are in a molten or partially molten state to bond the second connection terminals and the corresponding fourth connection terminals with each other into stable interconnection bonds, wherein the second semiconductor device is maintained in a precisely aligned state.

The minimum surface energy principle based on the molten and partially molten state solder joint automatically leads each of the at least one first semiconductor device and the at least one second semiconductor device to its target position to achieve the surface energy minimization, and the alignment solder joint enables the semiconductor device to be fixed at the target position accurately after solidification and substantial solidification. By optimizing the design of the first and third alignment solder parts, the second and fourth alignment solder parts (e.g., in terms of volume, geometry, composition, location, distribution, number, etc.), accurate, efficient, and reliable self-alignment capability can be achieved. Accurate alignment of the at least one first semiconductor device and the at least one second semiconductor device also ensures the accurate alignment of the first connection terminals and the third connection terminals, and the second connection terminals and the fourth connection terminals. In view of the self-aligning capability of the alignment solder joints, a certain degree of placement deviation is allowed when the at least one first semiconductor device and the at least one second semiconductor device are picked up and placed, so that the requirement on the placement accuracy of the at least one first semiconductor device and the at least one second semiconductor device can be obviously reduced, the speed of the picking-up and placing operation for the at least one first semiconductor device and the at least one second semiconductor device can be obviously increased, the process efficiency is improved, and the process and equipment cost is reduced.

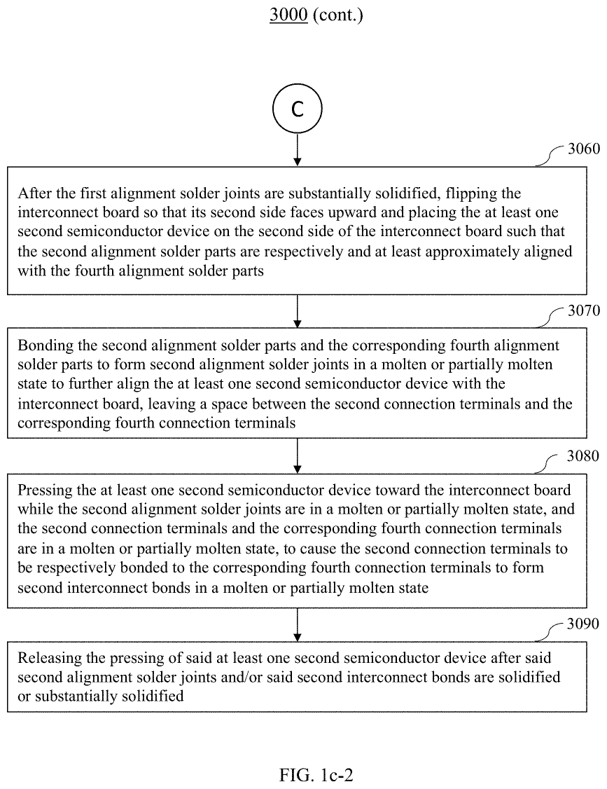

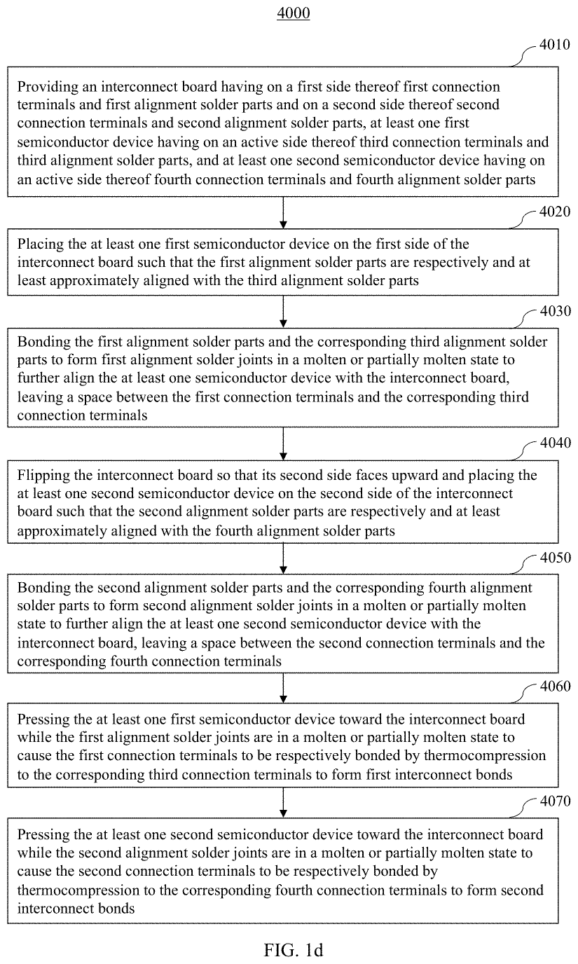

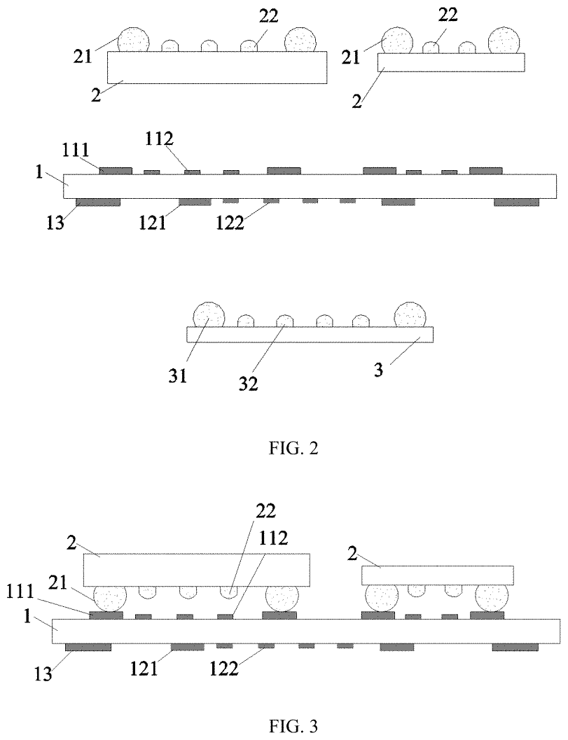

FIG. 1b (which for ease of illustration is split into FIG. 1b-1 and FIG. 1b-2 on two pages) illustrates a method 2000 of forming a semiconductor assembly as including Steps 2010-2090, which are described below with reference to FIGS. 2 to 8, according to some embodiments.

Step 2010—providing an interconnect board 1, at least one first semiconductor device 2, and at least one second semiconductor device 3.

In some embodiments, a plurality of first connection terminals 112 and a plurality of first alignment solder parts 111 are formed on a first surface of the interconnect board 1, and a plurality of second connection terminals 122 and a plurality of second alignment solder parts 121 are formed on a second surface of the interconnect board 1, the second surface being opposite to the first surface. In some embodiments, a plurality of third connection terminals 22 and a plurality of third alignment solder parts 21 are formed on an active surface of each of the at least one first semiconductor device 1, and a plurality of fourth connection terminals 32 and a plurality of fourth alignment solder parts 31 are formed on an active surface of each of the at least one second semiconductor device 3. In some embodiments, the first connection terminals 112 and the third connection terminals 22 are in one-to-one correspondence, the first alignment solder parts 111 and the third alignment solder parts 21 are in one-to-one correspondence. Likewise, the second connection terminals 122 and the fourth connection terminals 32 are in one-to-one correspondence, the second alignment solder parts 121 and the fourth alignment solder parts 31 are in one-to-one correspondence. In some embodiments, a sum of a height of any first connection terminal 112 and that of a corresponding third connection terminal 22 is smaller than a sum of a height of any one of the first alignment solder parts 111 and that of a corresponding one of the third alignment solder parts 21. Likewise, a sum of a height of any second connection terminal 122 and that of a corresponding fourth connection terminal 32 is smaller than a sum of a height of any one of the second alignment solder parts 121 and that of a corresponding one of the fourth alignment solder parts 31.

In some embodiments, the at least one first semiconductor device 2 includes a plurality of first semiconductor devices 2, which may include semiconductor devices that are different from each other at least in part in function, size, or shape, or may be the same as each other.

In some embodiments, the at least one second semiconductor device 3 includes a plurality of second semiconductor devices 3, which may include semiconductor devices that are different from each other at least in part in function, size, or shape, or may be the same as each other.

The material of the interconnect board is not limited in this application, for example, the material of the interconnect board may be silicon, organic polymer, glass, ceramic or metal, or a combination of the above materials. In some embodiments, the interconnect board is also referred to as a substrate. In other embodiments, the interconnect board is also referred to as an interposer. The interconnect board can be any board material that can be used for receiving the at least one semiconductor device and realizing signal interconnection with the at least one semiconductor device.

In some embodiments, either one of a first alignment solder part 111 and a second alignment solder part 21 is an alignment solder bump and the other is an alignment pad corresponding to the alignment solder bump. In other embodiments, the first alignment solder part 111 and the second alignment solder part 21 are both alignment solder bumps, and the melting points of the first alignment solder part 111 and the second alignment solder part 21 can be the same or different.

In some embodiments, either one of a second alignment solder part 121 and a fourth alignment solder part 31 is an alignment solder bump and the other is an alignment pad corresponding to the alignment solder bump. In other embodiments, the second alignment solder part 121 and the fourth alignment solder part 31 are both alignment solder bumps, and the melting points of the second alignment solder part 121 and the fourth alignment solder part 31 can be the same or different.

The solder bumps are made of solder, for example, and the alignment solder joints are formed by melting the solder in a subsequent step.

By way of example, alignment solder bumps may be pre-fabricated on a semiconductor device (e.g., a wafer) or a carrier using a bumping process (e.g., electroplating, ball-planting, stencil printing, evaporation/sputtering, etc.) known in the art. As an example, alignment pads may be fabricated on the semiconductor device or the interconnect board in advance using a deposition (e.g., metal layer) —photolithography-etching process. Any other solder configuration or form may be used as long as the first and second alignment solder parts are capable of being soldered to each other for alignment purposes.

In some embodiments, the first alignment solder parts and the third alignment solder parts correspond to each other in volume, size, geometry, composition, distribution, location, and number, so that each of the at least one semiconductor device can be precisely aligned to its respective target position on the interconnect board by soldering each first alignment solder part and a corresponding third alignment solder part to each other. Likewise, the second alignment solder parts and the fourth alignment solders correspond to each other in volume, size, geometry, composition, distribution, location, and number, so that each of the at least one semiconductor device can be precisely aligned to its respective target position on the interconnect board by soldering each second alignment solder part and a corresponding fourth alignment solder part to each other.

In some embodiments, the first or second connection terminals are solder bumps, and the third or fourth connection terminals are solder pads respectively corresponding to the solder bumps. Or, the third or fourth connection terminals are solder bumps, and the first or second connection terminals are solder pads respectively corresponding to the solder bump. Or, the first connection terminals and the third connection terminals are all solder bumps, and the second connection terminals and the fourth connection terminals are all solder bumps.

The solder bumps are made of solder, for example, and the interconnection bonds are formed by melting the solder in a subsequent step.

Referring to FIG. 2, a plurality of first alignment solder parts 111 and a plurality of first connection terminals 112 are formed on a first surface on a first side of the interconnect board 1, and a plurality of second alignment solder parts 111 and a plurality of first connection terminals 122 are formed on a second surface on a second side of the interconnect board 1. In Step 2010, two first semiconductor devices 1 (e.g., two first semiconductor devices of different sizes) and one second semiconductor device 3 (e.g., one second semiconductor device of a different size from that of any of the first semiconductor devices) are provided. A plurality of second alignment solder parts 21 and a plurality of second connection terminals 22 are formed on the active surface of the semiconductor devices 2. A plurality of fourth alignment solder parts 31 and a plurality of second connection terminals 32 are formed on the active surface of the semiconductor device 3.

Step 2020—placing the at least one first semiconductor device 2 on the first side of the interconnect board 1 such that each first alignment solder part 111 is substantially (or approximately) aligned with a corresponding third alignment solder part 21.

In some embodiments, “substantial alignment” or “approximate alignment” may mean that the first alignment solder parts 111 and the corresponding third alignment solder parts 21 are respectively in contact with each other, without being precisely centered in a direction perpendicular to the passive or active surface of a semiconductor device (e.g., the orthographic projections of the centers of a first alignment solder part 111 and the corresponding third alignment solder part 21 on a plane parallel to the first or second surface of the interconnect board 1 is allowed to deviate from each other). Here, “centered” is generally meant that the centers of the first and second alignment solder parts are aligned in a direction perpendicular to the active or passive surface of the semiconductor device involved.

In some embodiments, “substantial alignment” of the first alignment solder parts with the second alignment solder parts means that there is at least contact between the first alignment solder parts and the second alignment solder parts to the extent that self-alignment is possible by virtue of the principle of minimum surface energy of the alignment solder joint in a molten or partially molten state during soldering, as described below. Thus, “substantial alignment” includes a state of imprecise alignment but at least physical contact, but may not exclude a state of exact alignment.

Referring to FIG. 3, when the at least one semiconductor device 2 is placed on the first surface of the interconnect board 1 in step 1020, the active surface of the at least one semiconductor device 2 faces the interconnect board 1 (i.e., the surface on which the first alignment solder 111 is formed), and the passive surface of the at least one semiconductor device 2 faces away from the interconnect board 1. In this step, the at least one semiconductor device 2 and the interconnect board 1 do not require perfect alignment.

Step 2030—bonding the first alignment solder parts 111 and the corresponding third alignment solder parts 21 to each other to form first alignment solder joints a1 in a molten or partially molten state by using a bonding process to align precisely or more precisely the at least one semiconductor device 1. In some embodiments, a space is left between the first connection terminals 112 and the corresponding third connection terminals 22.

In some embodiments, “precise alignment” indicates a state where a deviation between an actual position and a target position of a semiconductor device 2 on the interconnect board 1 is within a preset tolerance in the art. In some embodiments, precise alignment is achieved using the principle of minimum surface energy exhibited by the solder joint or bonds a1 formed by soldering the first and third alignment solder parts 111 and 21 in a molten or partially molten state during soldering. In particular, when the first alignment solder parts 111 and the third alignment solder parts 21 are respectively in contact with each other but are not precisely centered in a direction perpendicular to the active surface of the semiconductor device 2 or the interconnect board 1, in the soldering process, one of a first alignment solder part 111 and a corresponding third alignment solder part 21 which is an alignment solder bump is melted or partially melted and wets the other one which is an alignment solder pad or another alignment solder bump, or both the first and third alignment solder parts melt or partially melt as alignment solder part bumps, thereby forming an alignment solder joint a1 in a molten or partially molten state. In some embodiments, the alignment solder joint a1 in the molten or partially molten state tends to move if there is any deformation based on a minimum surface energy principle to bring the first alignment solder part and the third alignment solder part closer to a centered state, thereby driving the semiconductor device 2 which is lighter relative to the interconnect board 1 to be accurately aligned to the target position on the interconnect board.

In some embodiments, after the first alignment solder parts 111 and the third alignment solder parts 21 are bonded, the active surface of the semiconductor device(s) 2 and the interconnect board 1 are spaced apart to form a space therebetween due to the height of the alignment solder joints a1 (in a direction perpendicular to the active surface of the semiconductor device or the interconnect board) formed thereby. Furthermore, a space is left between each first connection terminal 112 and its corresponding third connection terminal 22. In other words, each first connection terminal 112 and its corresponding third connection terminal 22 are spaced apart at this time.

The first and third connection terminals 112 and 22 may have a melting point higher than or lower than a temperature at which the first and third alignment solder parts 111 and 21 are bonded to form the alignment solder joint a1. When each first alignment solder part 111 and a corresponding third alignment solder part 21 are fused together, the first connection terminals 112 and/or the third connection terminals 22 may be in a solid state or may be in a molten or partially molten state. Since the first connection terminals 112 and the third connection terminals 22 are separated from each other at this time, they are not bonded together to form an interconnection bond b1.

In some embodiments, the alignment solder bump is made of solder, and soldering may be performed by various means known in the art for melting solder, including but not limited to reflow soldering, laser soldering, high frequency soldering, infrared soldering, and the like.

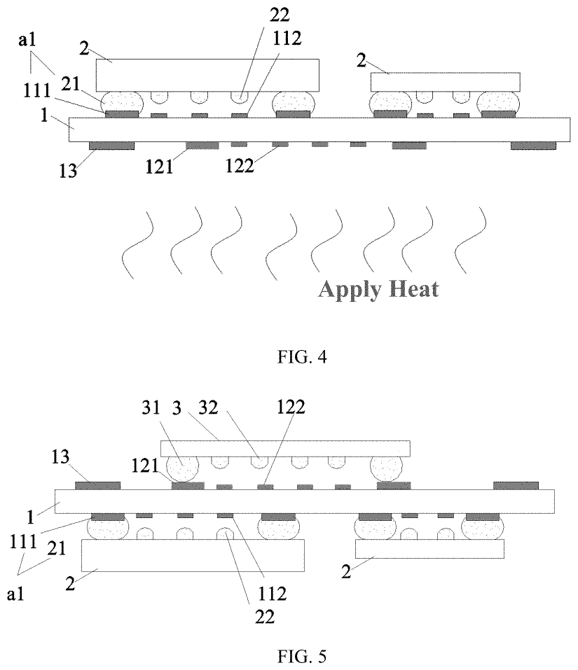

Referring to FIG. 4, each first alignment solder part 111 is in the form of a pad, and each third alignment solder part 21 is in the form of a solder bump. When a third alignment solder part 21 is in a molten state and wets a corresponding first alignment solder part 111, the third alignment solder part 21 tends to move automatically to the center of the first alignment solder part 111 to achieve minimum surface energy. As a result, the semiconductor device 2 is driven to move automatically to the target or expected position. Each first alignment solder part 111 and a corresponding third alignment solder part 21 are bonded to form an alignment solder joint a1. In this way, the self-alignment between the interconnect board 1 and the semiconductor device 2 is accomplished.

Comparing to FIG. 3, FIG. 4 shows that the semiconductor device 2 is automatically moved to a targeted position and becomes more accurately aligned with the interconnect board 1 during the soldering process.

Step 2040—after the first alignment solder joint a1 is in a cured or substantially cured state, flipping the interconnect board 1 so that its second side faces upward (e.g., away from the earth).

In this step, the interconnect board 1 is turned upside down so that its second side faces upwards, and its first side faces downwards. To ensure that the alignment state of each first semiconductor device 2 is not affected, the first alignment solder joints a1 are solidified or substantially solidified in step 1002 and the first connection terminal 112 and/or the second connection terminal 122 returns to the solidified or substantially solidified state before the interconnect board 1 is turned over.

In some embodiments, “substantial alignment” of the second alignment solder parts 121 with the fourth alignment solder parts 31 means that there is at least contact between the second alignment solder parts 121 and the fourth alignment solder parts 31 to the extent that self-alignment is possible by virtue of the principle of minimum surface energy of the alignment solder joints in a molten or partially molten state during soldering, as described below. Thus, “substantial alignment” includes a state of imprecise alignment but at least physical contact, but may not exclude a state of exact alignment.

Referring to FIG. 5, when the at least one second semiconductor device 3 is placed on the second side of the interconnect board 1 in step 2040, the active surface of the at least one second semiconductor device 3 faces the interconnect board 1 (i.e., the surface on which the second alignment solder parts 121 is formed), and the passive surface of the at least one second semiconductor device 3 faces away from the interconnect board 1. In this step, the at least one second semiconductor device 3 and the interconnect board 1 do not require precise alignment.

Step 2050—bonding the second alignment solder parts 121 and the corresponding fourth alignment solder parts 31 respectively to each other to form second alignment solder joints a2 in a molten or partially molten state by using a bonding process to align precisely or more precisely the at least one second semiconductor device 3. In some embodiments, a space is left between the second connection terminals 122 and the corresponding fourth connection terminals 32.

In some embodiments, “precise alignment” indicates a state where a deviation between an actual position and a target position of a semiconductor device 3 on the interconnect board 1 is within a preset tolerance in the art. In some embodiments, precise alignment is achieved using the principle of minimum surface energy exhibited by the solder joint or bonds a1 formed by soldering the second and fourth alignment solder parts 121 and 31 in a molten or partially molten state during soldering. In particular, when the second alignment solder parts 121 and the fourth alignment solder parts 31 are respectively in contact with each other but are not precisely centered in a direction perpendicular to the active surface of the semiconductor device 3 or the interconnect board 1, in the soldering process, one of a second alignment solder part 121 and a corresponding fourth alignment solder part 31 which is an alignment solder bump is melted or partially melted and wets the other one which is an alignment solder pad or another alignment solder bump, or both the second and fourth alignment solder parts melt or partially melt as alignment solder part bumps, thereby forming an alignment solder joint a2 in a molten or partially molten state. In some embodiments, the alignment solder joint a2 in the molten or partially molten state tends to move if there is any deformation based on a minimum surface energy principle to bring the second alignment solder part 121 and the fourth alignment solder part 31 closer to a centered state, thereby driving the semiconductor device 3 which is lighter relative to the interconnect board 1 to be accurately aligned to the target position on the interconnect board.

In some embodiments, after the second alignment solder parts 121 and the fourth alignment solder parts 31 are bonded, the active surface of the semiconductor device(s) 3 and the interconnect board 1 are spaced apart to form a space therebetween due to the height of the alignment solder joints a2 (in a direction perpendicular to the active surface of the semiconductor device or the interconnect board) formed thereby. A space is left between each second connection terminal 122 and its corresponding fourth connection terminal 32. In other words, so that each second connection terminal 122 and the corresponding fourth connection terminal 32 are spaced apart at this time.

The second and fourth connection terminals 122 and 32 may have a melting point higher than or lower than a temperature at which the second and fourth alignment solder parts 121 and 31 are bonded to form the alignment solder joint a2. When each second alignment solder part 121 and a corresponding fourth alignment solder part 31 are fused together, the second connection terminals 122 and/or the fourth connection terminals 32 may be in a solid state or may be in a molten state. Since the second connection terminals 112 and the fourth connection terminals 32 are separated from each other at this time, they are not bonded together to form an interconnection bond b2.

In some embodiments, the alignment solder bump is made of solder, and the soldering may be performed by various means known in the art for melting solder, including but not limited to reflow soldering, laser soldering, high frequency soldering, infrared soldering, and the like.

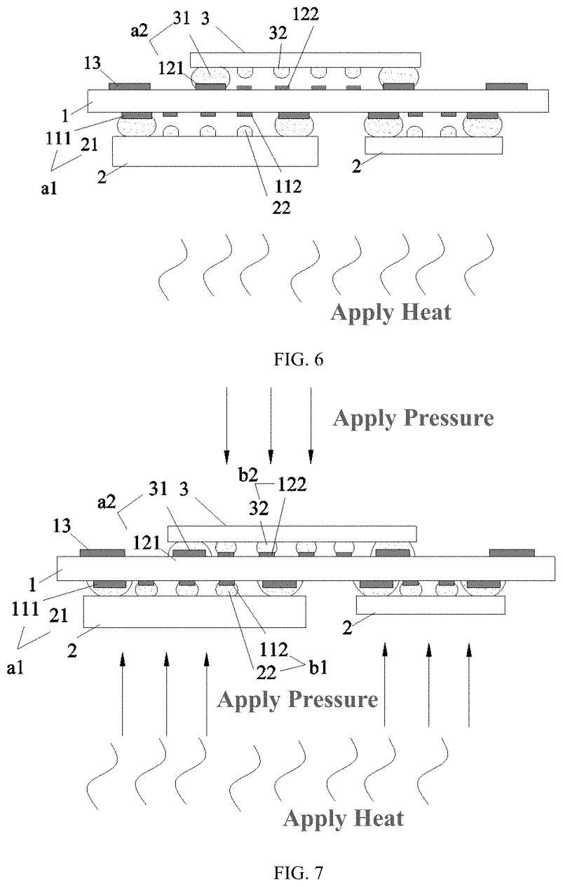

Referring to FIG. 6, each second alignment solder part 121 is in the form of a pad, and each fourth alignment solder part 31 is in the form of a solder bump. When a fourth alignment solder part 31 is in a molten state and wets a corresponding second alignment solder part 121, the fourth alignment solder part 31 tends to move automatically to the center of the second alignment solder part 121 to achieve minimum surface energy. As a result, the semiconductor device 3 is driven to move automatically to the target or expected position. Each second alignment solder part 121 and a corresponding fourth alignment solder part 31 are bonded to form the alignment solder joints a2. In this way, the self-alignment between the interconnect board 1 and the semiconductor device 3 is accomplished.

In some embodiments, the interconnect board 1 and the first semiconductor device 2 are supported so that the relative positions of the two remain unchanged during Step 2050.

Step 2060—pressing the at least one first semiconductor device 2 towards the interconnect board 1 while the alignment solder joints a1 are in a molten or partially molten state and the first connection terminals 112 and/or the third connection terminals 22 are in a molten or partially molten state, so that the first connection terminals 112 and the corresponding third connection terminals 22 are respectively bonded to each other into interconnection bonds b1 in a molten or partially molten state.

Since the position of each semiconductor device 2 is at an expected position of the semiconductor device, the first connection terminals 112 and the third connection terminals 22 are opposite to each other, respectively, so pressing the semiconductor device 2 towards the interconnect board 1 causes the first connection terminals 112 and the third connection terminals 22 be respectively centered and bonded to form interconnection bonds b1, resulting in good electrical connections between the semiconductor device 2 and the interconnect board 1.

Referring to FIG. 7, the first alignment solder joints a1 are squashed in Step 2060 so that the first connection terminals 112 and the corresponding third connection terminals 22 are brought together and bonded to form first interconnection bonds b1.

In some embodiments, the first semiconductor device 2 may be pressed with a platen toward the interconnect board 1.

Step 2070—pressing the at least one second semiconductor device 3 towards the interconnect board 1 while the alignment solder joints a2 are in a molten or partially molten state and the second connection terminals 122 and/or the fourth connection terminals 32 are in a molten or partially molten state, so that the second connection terminals 122 and the corresponding fourth connection terminals 32 are respectively bonded to each other into interconnection bonds b2 in a molten or partially molten state.

Since the position of each semiconductor device 3 is an expected position of the semiconductor device, the second connection terminals 122 and the fourth connection terminals 32 are opposite to each other, respectively, pressing the semiconductor device 3 towards the interconnect board 1 causes the second connection terminals 122 and the fourth connection terminals 32 be respectively centered and bonded to form interconnection bonds b2, resulting in good electrical connections between the semiconductor device 3 and the interconnect board 1.

Referring to FIG. 7, the second alignment solder joints a2 are squashed in Step 2070 so that the second connection terminals 122 and the corresponding fourth connection terminals 32 are brought together and bonded to form second interconnection bonds b2.

In some embodiments, the second semiconductor device 3 may be pressed with a platen toward the interconnect board 1.

In some embodiments, Steps 2060 and 2070 are performed concurrently, i.e., the action of pressing the at least one first semiconductor device 2 towards the interconnect board 1 and the action of pressing the at least one second semiconductor device 3 towards the interconnect board 1 are carried out concurrently.

The melting temperatures, or the temperatures at which the first alignment solder joint a1, the second alignment solder joint a2, the first connection terminal 112 and/or the third connection terminal 22, the second connection terminal 122 and/or the fourth connection terminal 32 are at a molten or partially molten state may be the same or different. In some alternative embodiments, when the temperature is high enough that the first alignment solder joint a1, the second alignment solder joint a2, the first connection terminal 112 and/or the third connection terminal 22, the second connection terminal 122 and/or the fourth connection terminal 32 are all in a molten or partially molten state, the first semiconductor device 2 and the second semiconductor device 3 are simultaneously pressed towards the interconnect board 1, thereby concurrently bonding the first connection terminals 112 to the third connection terminals 22, and the second connection terminals 122 to the fourth connection terminals 32.

In other embodiments, the temperature is increased in Step 2060 to cause the first alignment solder joints a1 to melt or partially melt and the first connection terminal 112 and/or the third connection terminal 22 to melt or partially melt first, and the temperature is further increased in Step 2070 when the second semiconductor device 3 is pressed toward the interconnect board 1 until the second alignment solder joints a2 melt or partially melt and the second connection terminals 122 and/or the fourth connection terminals 32 are in the molten or partially molten state.

In other embodiments, step 2070 is performed first and the temperature is increased causing the second alignment solder joints a2 to melt or partially melt and the second connection terminal 122 and/or the fourth connection terminal 32 to melt or partially melt first, and then, as the temperature further increases, the first semiconductor device 2 is pressed toward the interconnect board 1 until the first alignment solder joints a1 melt or partially melt and the first connection terminal 112 and/or the third connection terminal 22 are in the molten or partially molten state.

Step 2080—releasing the pressing of said at least one first semiconductor device 2 after said first alignment solder joints a1 and/or said first interconnect bonds b1 are solidified or substantially solidified.

The precondition for releasing the pressing of the at least one first semiconductor device 2 is that the shapes of the first alignment solder joints a1 and the first interconnection bonds b1 are stable, and those skilled in the art can flexibly adjust the timing, force, pressing distance, pressing time, etc. before releasing the pressing of the at least one first semiconductor device 2 according to actual implementation.

Step 2090—releasing the pressing of the at least one second semiconductor device 3 after the solidification or substantially solidification of the second alignment solder joints a2 and/or the second interconnect bonds b2.

The precondition for releasing the pressing of the at least one second semiconductor device 3 is that the shapes of the second alignment solder joints a2 and the second interconnection bonds b2 are stable, and those skilled in the art can flexibly adjust the timing, the acting force, the pressing distance, the pressing time, etc. for releasing the pressing of the at least one second semiconductor device 3 according to actual conditions.

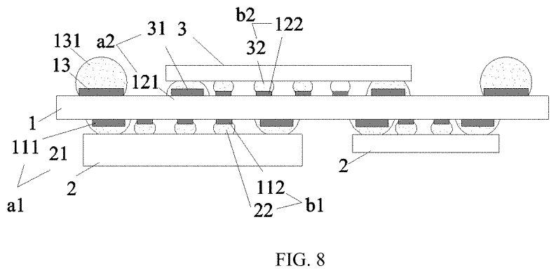

Referring to FIG. 8, after the soldering is completed, the first alignment solder joints a1, the second alignment solder joints a2, the first interconnection bonds b1, and the second interconnection bonds b2 are solidified at desired positions.

The semiconductor device is thus automatically precisely introduced to the target position based on the principle of minimum surface energy to achieve surface energy minimization, and the solder joints are aligned so that the semiconductor device is firmly and accurately fixed at the target position. By optimizing the design for the first and second alignment solder parts 111 and 121 (e.g., for aspects of volume, geometry, composition, location, distribution, and quantity, etc.), accurate, efficient, and reliable self-alignment capability can be achieved. The accurate alignment of the semiconductor device also ensures accurate alignment of each first connection terminal and the corresponding third connection terminal, and accurate alignment of each second connection terminal and the corresponding fourth connection terminal. A certain degree of placement deviation is allowed when picking up and placing the semiconductor device in view of the self-alignment capability of the alignment solder joints, so that the requirement on the placement accuracy of the semiconductor device can be significantly reduced, and the speed of the semiconductor device picking-up and placing operation can be significantly increased, thereby improving the process efficiency and reducing the process and equipment costs.

It should be noted that steps 2010 to 2090 are not limited to be executed in sequence or in the order described and/or illustrated. For example, in some of the aforementioned variations, step 2060 and step 2070 may be performed sequentially, overlappingly, or simultaneously, or step 2070 may be performed first, and then step 2060 may be performed.

In some embodiments, external pads 13 are further formed on the first and/or second side of the interconnect board 1, and the method further comprises forming a solder bumps 131 on the external pads 13.

The external pads 13 serve to interconnect the semiconductor assembly or package to other components to form an electronic product or system.

The solder bumps 131 facilitate interconnection of the semiconductor package with other components.

Referring to FIG. 8, external pads 13 and solder bumps 131 are formed on the second side of the interconnect board 1.

In some embodiments, one interconnect board 1 is used to form one semiconductor component.

In other embodiments, to improve production efficiency, the interconnect board is large enough to allow a number of semiconductor devices to be assembled on its first and second sides such that after the semiconductor devices are connected to the interconnect board 1, as described above, the interconnect board needs to be diced to obtain a plurality of semiconductor assemblies. Thus, in some embodiments, the method 2000 further comprises dicing the interconnect board 1 to obtain a plurality of semiconductor assemblies. Each semiconductor assembly includes at least one first semiconductor device 2, at least one second semiconductor device 3, and a segmented portion of the interconnect board 1.

In some embodiments, when the interconnect board 1 is diced, some or all of the alignment solder joints a1 and/or b1 are also cut off. In some embodiments, when the interconnect board 1 is diced, at least some of the alignment solder joints a1 and b1 are retained, which may serve the function of connecting electrical signals, power supply potential, for grounding, or for mechanical attachment and heat dissipation, among other functions.

As shown in FIG. 1c, which for ease of illustration is split into FIG. 1c-1 and FIG. 1c-2 on two pages, a semiconductor assembly packaging method 3000 according to some embodiments includes steps 3010-3090, as described below.

Step 3010—providing an interconnect board, at least one first semiconductor device, and at least one second semiconductor device.

In some embodiments, a plurality of first connection terminals and a plurality of first alignment solder parts are formed on a first surface on a first side of the interconnect board, and a plurality of second connection terminals and a plurality of second alignment solder parts are formed on a second surface on a second side of the interconnect board, the second surface being opposite to the first surface. In some embodiments, a plurality of third connection terminals and a plurality of third alignment solder parts are formed on an active surface of each of the at least one first semiconductor device, and a plurality of fourth connection terminals and a plurality of fourth alignment solder parts are formed on an active surface of each of the at least one second semiconductor device. In some embodiments, the first connection terminals and the third connection terminals are in one-to-one correspondence, the first alignment solder parts and the third alignment solder parts are in one-to-one correspondence. Likewise, the second connection terminals and the fourth connection terminals are in one-to-one correspondence, the second alignment solder parts and the fourth alignment solder parts are in one-to-one correspondence. In some embodiments, a sum of a height of any first connection terminal and that of a corresponding third connection terminal is smaller than a sum of a height of any one of the first alignment solder parts and that of a corresponding one of the third alignment solder parts. Likewise, a sum of a height of any second connection terminal and that of a corresponding fourth connection terminal is smaller than a sum of a height of any one of the second alignment solder parts and that of a corresponding one of the fourth alignment solder parts.

Step 3020—placing the at least one first semiconductor device on the first side of the interconnect board such that the first alignment bond is substantially aligned with the corresponding third alignment bond.

Step 3030—bonding the first alignment solder part parts and the corresponding third alignment solder parts to form first alignment solder joints in a molten or partially molten state using a soldering process to more accurately align the at least one first semiconductor device. In some embodiments, the first connection terminals and the corresponding third connection terminals are spaced apart from each other after the first alignment solder joints are formed.

Step 3040—pressing the at least one first semiconductor device towards the interconnect board while the first alignment solder joints are in a molten or partially molten state and the first connection terminals and the corresponding third connection terminals are in a molten or partially molten state, so that the first connection terminals and the corresponding third connection terminals are brought together and bonded to form interconnection bonds in a molten or partially molten state.

In some embodiments, after the first alignment solder joints are solidified or substantially solidified, the first alignment solder joints are melted or partially melted again using soldering process and the first connection terminals and/or the third connection terminals are brought into a molten or partially molten state before pressing the at least one first semiconductor device towards the interconnect board.

Alternatively, the first alignment solder joints are kept in a molten or partially molten state after they are formed, and the first connection terminals and/or the third connection terminals are brought into a molten or partially molten state before pressing the at least one first semiconductor device towards the interconnect board.

Step 3050—releasing the pressing of said at least one first semiconductor device after said first alignment solder joints and/or said first interconnect bonds are solidified or substantially solidified.

Step 3060—after the first alignment solder joints and/or said first interconnect bonds are in a solidified or substantially solidified state, flipping the interconnect board so that its second side faces upward, and placing the at least one second semiconductor device on the second side of the interconnect board such that the second alignment bond is substantially aligned with a corresponding fourth alignment bond.

In some embodiments, alignment and uniform spacing between the at least one first semiconductor device and the interconnect board are maintained as the interconnect board is flipped to allow assembling of the at least one second semiconductor device to the interconnect board.

In the above embodiments, when the interconnection board is turned over in Step 3060, fixing means can be used to fix the at least one first semiconductor device relative to the interconnection board.

In this manner, the first semiconductor device is not displaced or dropped during flipping of the interconnect board, regardless of whether the first alignment solder joints are in a molten or partially molten state, and regardless of whether the first interconnect bonds (if formed at this time) are in a molten or partially molten state.

Step 3070—bonding the second alignment solder part parts and the corresponding fourth alignment solder part parts to form second alignment solder joints in a molten or partially molten state using a soldering process to more accurately align the at least one second semiconductor device. In some embodiments, the second connection terminals and the corresponding fourth connection terminals are spaced apart from each other after the second alignment solder joints are formed, and a relative position of the interconnection board and the at least one first semiconductor device is maintained in Step 3070.

Step 3080—pressing the at least one second semiconductor device towards the interconnect board while the second alignment solder parts are in a molten or partially molten state and the second connection terminals and the corresponding fourth connection terminals are in a molten or partially molten state so that the second connection terminals and the corresponding fourth connection terminals are bonded to form second interconnection bonds in a molten or partially molten state.

In some embodiments, after the second alignment solder joints are solidified or substantially solidified, the second alignment solder joints are melted or partially melted again using soldering process and the second connection terminals and/or the fourth connection terminals are brought into a molten or partially molten state before pressing the at least one second semiconductor device towards the interconnect board.

Alternatively, the second alignment solder joints are kept in a molten or partially molten state after they are formed, and the second connection terminals and/or the fourth connection terminals are brought into a molten or partially molten state before pressing the at least one second semiconductor device towards the interconnect board.

Step 3090—releasing the pressing of said at least one second semiconductor device after said second alignment solder joints and/or said second interconnect bonds are solidified or substantially solidified

In method 3000, the self-alignment of the first semiconductor device and the bonding of the interconnect terminals are first completed, and then the interconnect board is flipped over to perform the self-alignment of the second semiconductor device and the bonding of the interconnect terminals.

In some embodiments, because the temperature of the whole interconnect board is high during the self-alignment of the second semiconductor device and the bonding of the interconnect terminals, the first alignment solder joints and the first interconnect bonds may be melted or partially melted, and the first semiconductor device needs to be supported, so as to ensure that the relative position of the interconnect board and the first semiconductor device is unchanged and the forms of the first alignment solder joints and the first interconnect bonds are unchanged. In some embodiments, the first alignment solder joints and the first interconnect bonds may also be in a solidified or partially solidified state during the bonding of the second semiconductor device, and no support for the first semiconductor device is required.

In some embodiments, either one of a first alignment solder part and a second alignment solder part is an alignment solder bump and the other is an alignment pad corresponding to the alignment solder bump. In other embodiments, the first alignment solder part and the second alignment solder part are both alignment solder bumps.

In some embodiments, either one of a second alignment solder part and a fourth alignment solder part is an alignment solder bump and the other is an alignment pad corresponding to the alignment solder bump. In other embodiments, the second alignment solder part and the fourth alignment solder part are both alignment solder bumps.

The solder bumps are made of solder, for example, and the alignment solder joints are formed by melting the solder in a subsequent step.

In some embodiments, the first or second connection terminals are solder bumps, and the third or fourth connection terminals are solder pads respectively corresponding to the solder bumps. Or, the third or fourth connection terminals are solder bumps, and the first or second connection terminals are solder pads respectively corresponding to the solder bump. Or, the first connection terminals and the third connection terminals are all solder bumps, and the second connection terminals and the fourth connection terminals are all solder bumps.

The solder bumps are made of solder, for example, and the interconnection bonds are formed by melting the solder.

In some embodiments, substantially aligning the first alignment solder parts with respectively ones of the third alignment solder parts comprises bringing each of the first alignment solder parts and a corresponding one of the third alignment solder parts into contact with each other while allowing orthographic projection of a center of any of the first solder parts and to deviate from alignment with orthographic projection of a center of a corresponding third solder part.

In some embodiments, substantially aligning the second alignment solder parts with respectively ones of the fourth alignment solder parts comprises bringing each of the second alignment solder parts and a corresponding one of the fourth alignment solder parts into contact with each other while allowing orthographic projection of a center of any of the second solder parts and to deviate from alignment with orthographic projection of a center of a corresponding fourth solder part.

In some embodiments, external pads are further formed on the first and/or second side of the interconnect board, and the method 3000 further comprises forming a solder bumps on the external pads.

In some embodiments, the method 3000 further comprises dicing the interconnect board to obtain a plurality of semiconductor assemblies. Each semiconductor assembly includes at least one first semiconductor device, at least one second semiconductor device, and a segmented portion of the interconnect board.

As shown in FIG. 1d, a semiconductor assembly packaging method 4000 according to some embodiments includes steps 4010-4090, as described below.

Step 4010—providing an interconnect board, at least one first semiconductor device, and at least one second semiconductor device.

In some embodiments, a plurality of first connection terminals and a plurality of first alignment solder parts are formed on a first surface on a first side of the interconnect board, and a plurality of second connection terminals and a plurality of second alignment solder parts are formed on a second surface on a second side of the interconnect board, the second surface being opposite to the first surface. In some embodiments, a plurality of third connection terminals and a plurality of third alignment solder parts are formed on an active surface of each of the at least one first semiconductor device, and a plurality of fourth connection terminals and a plurality of fourth alignment solder parts are formed on an active surface of each of the at least one second semiconductor device. In some embodiments, the first connection terminals and the third connection terminals are in one-to-one correspondence, the first alignment solder parts and the third alignment solder parts are in one-to-one correspondence. Likewise, the second connection terminals and the fourth connection terminals are in one-to-one correspondence, the second alignment solder parts and the fourth alignment solder parts are in one-to-one correspondence. In some embodiments, a sum of a height of any first connection terminal and that of a corresponding third connection terminal is smaller than a sum of a height of any one of the first alignment solder parts and that of a corresponding one of the third alignment solder parts. Likewise, a sum of a height of any second connection terminal and that of a corresponding fourth connection terminal is smaller than a sum of a height of any one of the second alignment solder parts and that of a corresponding one of the fourth alignment solder parts.

Step 4020—placing the at least one first semiconductor device on the first side of the interconnect board such that the first alignment bond is substantially aligned with the corresponding third alignment bond.

Step 4030—bonding the first alignment solder part parts and the corresponding third alignment solder parts to form first alignment solder joints in a molten or partially molten state using a soldering process to more accurately align the at least one first semiconductor device. In some embodiments, the first connection terminals and the corresponding third connection terminals are spaced apart from each other after the first alignment solder joints are formed.

Step 4040—after the first alignment solder joints are in a solidified or substantially solidified state, flipping the interconnect board so that its second side faces upward, and placing the at least one second semiconductor device on the second side of the interconnect board such that the second alignment bond is substantially aligned with a corresponding fourth alignment bond.

Step 4050—bonding the second alignment solder part parts and the corresponding fourth alignment solder part parts to form second alignment solder joints in a molten or partially molten state using a soldering process to more accurately align the at least one second semiconductor device. In some embodiments, the second connection terminals and the corresponding fourth connection terminals are spaced apart from each other after the second alignment solder joints are formed.

Step 4060—pressing the at least one first semiconductor device towards the interconnect board while the first alignment solder joints are in a molten or partially molten state, so that the first connection terminals and the corresponding third connection terminals are respectively bonded by thermocompression to form first interconnection bonds.

Step 4070—pressing the at least one second semiconductor device towards the interconnect board while the second alignment solder parts are in a molten or partially molten state, so that the second connection terminals and the corresponding fourth connection terminals are respectively bonded by thermocompression to form second interconnection bonds.

The method 4000 illustrated in FIG. 1d differs from methods 2000 and 3000 at least in that the first interconnection terminal and the third interconnection terminal are bonded by thermocompression bonding to form first interconnection bond, and the second interconnection terminal and the fourth interconnection terminal are bonded by thermocompression bonding to form second interconnection bond.

Since the mechanical strength of the interconnection bonds is sufficiently high to ensure that the relative position of the first semiconductor device and the interconnection board is stable, and the relative position of the second semiconductor device and the interconnection board is stable, the first alignment solder joints should not deform or move even in a molten or partially molten state when the pressing on the first semiconductor device is removed, and the second alignment solder joints should not deformed or moved even if the second alignment bonding part is in a molten or partially molten state when the pressing of the second semiconductor device is removed.

Steps 4010 to 4070 may be performed sequentially. Namely, the self-alignment of the first semiconductor device and the second semiconductor device is first achieved and then both are pressed.

In some embodiments, the execution sequence of the above steps may be step 4010, step 4020, step 4030, step 4060, step 4040, step 4050, and step 4070. Namely, the self-alignment of the first semiconductor device and the formation of the first interconnection bonds are firstly realized, and then the self-alignment of the second semiconductor device and the formation of the second interconnection bonds are realized.

In some embodiments, the action of pressing the at least one first semiconductor device towards the interconnect board and the action of pressing the at least one second semiconductor device towards the interconnect board are carried out concurrently.

In some embodiments, either one of a first alignment solder part and a second alignment solder part is an alignment solder bump and the other is an alignment pad corresponding to the alignment solder bump. In other embodiments, the first alignment solder part and the second alignment solder part are both alignment solder bumps.

In some embodiments, either one of a second alignment solder part and a fourth alignment solder part is an alignment solder bump and the other is an alignment pad corresponding to the alignment solder bump. In other embodiments, the second alignment solder part and the fourth alignment solder part are both alignment solder bumps.

The solder bumps are made of solder, for example, and the alignment solder joints are formed by melting the solder in a subsequent step.

In some embodiments, substantially aligning the first alignment solder parts with respectively ones of the third alignment solder parts comprises bringing each of the first alignment solder parts and a corresponding one of the third alignment solder parts into contact with each other while allowing orthographic projection of a center of any of the first solder parts and to deviate from alignment with orthographic projection of a center of a corresponding third solder part.

In some embodiments, substantially aligning the second alignment solder parts with respectively ones of the fourth alignment solder parts comprises bringing each of the second alignment solder parts and a corresponding one of the fourth alignment solder parts into contact with each other while allowing orthographic projection of a center of any of the second solder parts and to deviate from alignment with orthographic projection of a center of a corresponding fourth solder part.

In some embodiments, external pads are further formed on the first and/or second side of the interconnect board, and the method 4000 further comprises forming a solder bumps on the external pads.

In some embodiments, the method 4000 further comprises dicing the interconnect board to obtain a plurality of semiconductor assemblies. Each semiconductor assembly includes at least one first semiconductor device, at least one second semiconductor device, and a segmented portion of the interconnect board.

In some embodiments, the interconnection pads in the same semiconductor component may also be of different types. For example, some of the interconnect pads are solder formed interconnect pads, and another portion of the interconnect pads are Thermal Compression Bonding (TCB) formed interconnect pads.

In method 4000, the first semiconductor device may be pressed by using the pressing plate, and the second semiconductor device may be pressed using a pressing plate.

When the number of the at least one first semiconductor devices is plural and the thickness is different, the surface of the platen facing the first semiconductor device may be stepped instead planar. In other words, the area of the surface of the platen in contact with the thicker first semiconductor device is further away from the interconnect board. In some embodiments, even if the thickness of at least one first semiconductor device is equal, the pressing depth requirements can be different due to different properties of the respective second connection terminals, and the surface of the platen facing the interconnect board may still be stepped. The same is true for the case of pressing the second semiconductor device.

Embodiments of the present application also provide a semiconductor component made according to one of the aforementioned methods.

Embodiments of the present application also provide an electronic device, which includes the aforementioned semiconductor component.

The embodiments in the present application are described in a progressive manner, and the same and similar parts among the embodiments can be referred to each other, and each embodiment focuses on the differences from the other embodiments.

The protective scope of the present application is not limited to the above-described embodiments, and it is apparent that various modifications and variations can be made to the present application by those skilled in the art without departing from the scope and spirit of the present application. It is intended that the present application also include such modifications and variations as come within the scope of the appended claims and their equivalents.

What is claimed is:

1. A method of packaging a semiconductor assembly, comprising:
providing an interconnect board, at least one first semiconductor device, and at least one second semiconductor device, wherein the interconnect board has on a first side thereof first connection terminals and first alignment solder parts and on a second side thereof second connection terminals and second alignment solder parts, wherein the at least one first semiconductor device has on an active side thereof third connection terminals respectively corresponding to the plurality of first connection terminals, and third alignment solder parts respectively corresponding to the first alignment solder parts, wherein the at least one second semiconductor device has on an active side thereof fourth connection terminals respectively corresponding to the plurality of second connection terminals, and fourth alignment solder parts respectively corresponding to the second alignment solder parts;
placing the at least one first semiconductor device on the first side of the interconnect board such that the first alignment solder parts are respectively and at least approximately aligned with the third alignment solder parts;
bonding the first alignment solder parts and the corresponding third alignment solder parts to form first alignment solder joints in a molten or partially molten state to further align the at least one semiconductor device with the interconnect board such that the first connection terminals are respectively aligned with and spaced apart from the corresponding third connection terminals, leaving a space between the first connection terminals and the corresponding third connection terminal;
placing the at least one second semiconductor device on the second side of the interconnect board such that the second alignment solder parts are respectively and at least approximately aligned with the fourth alignment solder parts;
bonding the second alignment solder parts and the corresponding fourth alignment solder parts to form second alignment solder joints in a molten or partially molten state to further align the at least one second semiconductor device with the interconnect board such that the second connection terminals are respectively aligned with and spaced apart from the corresponding fourth connection terminals, leaving a space between the second connection terminals and the corresponding fourth connection terminal;
pressing the at least one first semiconductor device toward the interconnect board while the first alignment solder joints are in a molten or partially molten state to cause the first connection terminals to be respectively bonded to the corresponding third connection terminals; and
pressing the at least one second semiconductor device toward the interconnect board while the second alignment solder joints are in a molten or partially molten state to cause the second connection terminals to be respectively bonded to the corresponding fourth connection terminals.

2. The method of claim 1, further comprising, after the first alignment solder joints are in a solidified or substantially solidified state, flipping the interconnect board so that its second side faces upward before placing the at least one second semiconductor device on the second side of the interconnect board.

3. The method of claim 2, wherein:
the first connection terminals and the corresponding third connection terminals are in a molten or partially molten state when the at least one first semiconductor device is pressed toward the interconnect board to cause the first connection terminals to be respectively bonded to the corresponding third connection terminals to form first interconnect bonds in a molten or partially molten state; and
the second connection terminals and the corresponding fourth connection terminals are in a molten or partially molten state when the at least one second semiconductor device is pressed toward the interconnect board to cause the second connection terminals to be respectively bonded to the corresponding fourth connection terminals to form second interconnect bonds in a molten or partially molten state;
the method further comprising:
releasing the pressing of said at least one first semiconductor device after said first alignment solder joints and/or said first interconnect bonds are solidified or substantially solidified; and
releasing the pressing of said at least one second semiconductor device after said second alignment solder joints and/or said second interconnect bonds are solidified or substantially solidified.

4. The method of claim 3, wherein pressing the at least one first semiconductor device toward the interconnect board is performed concurrently with pressing the at least one second semiconductor device toward the interconnect board.

5. The method of claim 3, wherein the interconnect board is flipped so that its second side faces upward and the at least second semiconductor device are placed on the second side of the interconnect board after pressing the at least one first semiconductor device toward the interconnect board while the first alignment solder joints are in a molten or partially molten state and while the first connection terminals and the corresponding third connection terminals are in a molten or partially molten state, and releasing the pressing of said at least one first semiconductor device after said first alignment solder joints and/or said first interconnect bonds are solidified or substantially solidified.

6. The method of claim 1, wherein:
placing the at least one first semiconductor device on the first side of the interconnect board such that the first alignment solder parts are respectively and at least approximately aligned with the third alignment solder parts includes bringing the first alignment solder parts into contact with respective ones of the third alignment solder parts while allowing orthographic projection of a center of any of the first alignment solder parts and to deviate from alignment with orthographic projection of a center of a corresponding third solder part; and
placing the at least one second semiconductor device on the second side of the interconnect board such that the second alignment solder parts are respectively and at least approximately aligned with the fourth alignment solder parts includes bringing the second alignment solder parts into contact with respective ones of the fourth alignment solder parts while allowing orthographic projection of a center of any of the second alignment solder parts and to deviate from alignment with orthographic projection of a center of a corresponding fourth solder part.

7. The method of claim 1, further comprising:
forming external pads on the first side and/or the second side of the interconnect board; and
forming solder bumps on the external pads.

8. The method of claim 1, further comprising dicing the interconnect board to obtain a plurality of semiconductor assemblies, each semiconductor assembly including at least one first semiconductor device, at least one second semiconductor device, and a segmented portion of the interconnect board.

9. The method of claim 1, wherein the first connection terminals are respectively bonded to the corresponding third connection terminals to form first interconnect bonds, the method further comprising, after the first alignment solder joints and/or the first interconnect bonds are in a solidified or substantially solidified state, and before placing the at least one second semiconductor device on the second side of the interconnect board:
releasing the pressing of said at least one first semiconductor device; and
flipping the interconnect board so that its second side faces upward;
wherein the at least one semiconductor device is maintained at alignment with and uniform spacing from the interconnect board during and after flipping the interconnect board so that its second side faces upward.

10. The method of claim 1, further comprising flipping the interconnect board so that its second side faces upward before placing the at least one second semiconductor device on the second side of the interconnect board.

11. The method of claim 10, wherein the at least one first semiconductor device is pressed toward the interconnect board while the first alignment solder joints are in a molten or partially molten state to cause the first connection terminals to be respectively bonded by thermocompression to the corresponding third connection terminals.

12. The method of claim 11, wherein the at least one second semiconductor device is pressed toward the interconnect board while the second alignment solder joints are in a molten or partially molten state to cause the second connection terminals to be respectively bonded by thermocompression to the corresponding fourth connection terminals.

13. The method of claim 12, wherein pressing the at least one first semiconductor device toward the interconnect board is performed concurrently with pressing the at least one second semiconductor device toward the interconnect board.

14. The method of claim 1, wherein the at least one semiconductor device is pressed toward the interconnect board using a platen.

15. The method of claim 14, wherein a surface of the platen facing the at least one semiconductor device during the pressing is stepped.

16. The method of claim 1, wherein:
the first alignment solder parts are first solder bumps, and the third alignment solder parts are first solder pads corresponding to the first solder bumps; or
the third alignment solder parts are second solder bumps, and the first alignment solder parts are second solder pads corresponding to the second solder bumps; or
the third alignment solder parts are third solder bumps, and the first alignment solder parts are third solder pads corresponding to the third solder bumps.

17. The method of claim 16, wherein:
the second alignment solder parts are fourth solder bumps, and the fourth alignment solder parts are fourth solder pads corresponding to the fourth solder bumps; or
the fourth alignment solder parts are fifth solder bumps, and the second alignment solder parts are fifth solder pads corresponding to the fifth solder bumps; or
the fourth alignment solder parts are sixth solder bumps, and the second alignment solder parts are sixth solder pads corresponding to the sixth solder bumps.

18. The method of claim 1, wherein:
a sum of a height of any first connection terminal and that of a corresponding third connection terminal is smaller than a sum of a height of any first alignment solder part and that of a corresponding third alignment solder part; and
a sum of a height of any second connection terminal and that of a corresponding fourth connection terminal is smaller than a sum of a height of any second alignment solder part and that of a corresponding fourth alignment solder part.

19. A semiconductor component made according to the method of claim 1.

20. An electronic device including the semiconductor component according to claim 19.
